(19) United States
(12) Patent Application Publication
(10) Pub. No.: US 2024/0192604 A1
(43) Pub. Date: Jun. 13, 2024

(54) POST BAKING APPARATUS

(71) Applicant: SAMSUNG ELECTRONICS CO., LTD., Suwon-si (KR)

(72) Inventors: Jaehong LIM, Suwon-si (KR); Youngho HWANG, Suwon-si (KR); Byungjo KIM, Suwon-si (KR); Sangki NAM, Suwon-si (KR); Suyoung YOO, Suwon-si (KR); Sanghyun LIM, Suwon-si (KR); Youngkyun IM, Suwon-si (KR); Hyungkyu CHOI, Suwon-si (KR); Seok HEO, Suwon-si (KR)

(21) Appl. No.: 18/216,028

(22) Filed: Jun. 29, 2023

(30) Foreign Application Priority Data
Dec. 7, 2022 (KR) 10-2022-0169402

(51) Int. Cl. G03F 7/40

(52) U.S. Cl. CPC G03F 7/40

(57) ABSTRACT

A post baking apparatus comprising a baking chamber configured to receive a substrate with an exposed photoresist film, a lower heater in the baking chamber under the substrate to heat the exposed photoresist film, an applier applying an electric field or a magnetic field to the exposed photoresist film along a vertical direction, which is substantially perpendicular to an upper surface of the exposed photoresist film, to control diffusions of an acid or a secondary electron, which are generated from the exposed photoresist film, along a horizontal direction, and a controller configured to control an operation of the applier.

### CROSS-REFERENCE TO RELATED APPLICATIONS

Korean Patent Application No. 10-2022-0169402, filed on Dec. 7, 2022, in the Korean Intellectual Property Office, is incorporated herein by reference in its entirety.

### BACKGROUND

### 1. Field

A post baking apparatus and an exposure method using the same is disclosed.

### 2. Description of the Related Art

Generally, a pattern of a semiconductor device may be formed by a photolithography process.

### SUMMARY

Embodiments are directed to a post baking apparatus including a baking chamber configured to receive a substrate with an exposed photoresist film, a lower heater in the baking chamber under the substrate to heat the exposed photoresist film, an applier applying an electric field or a magnetic field to the exposed photoresist film along a vertical direction, which is substantially perpendicular to an upper surface of the exposed photoresist film, to control diffusions of an acid or a secondary electron, which are generated from the exposed photoresist film, along a horizontal direction, and a controller configured to control an operation of the applier.

Embodiments are directed to a post baking apparatus including a baking chamber configured to receive a substrate with an exposed photoresist film, a lower heater in the baking chamber under the substrate to heat the exposed photoresist film, a lower electrode under the lower heater, an upper electrode over the substrate to form an electric field from the lower electrode to the upper electrode along a vertical direction, a coil on an inner sidewall of the baking chamber to form a magnetic field from the upper electrode to the lower electrode along the vertical direction, and a controller configured to control operations of the lower heater, the lower electrode and the coil.

Embodiments are directed to a post baking apparatus including a baking chamber configured to receive a substrate with an exposed photoresist film, a lower heater in the baking chamber under the substrate to heat the exposed photoresist film, a lower electrode under the lower heater, an upper electrode over the substrate to form an electric field from the lower electrode to the upper electrode along a vertical direction, a coil on an inner sidewall of the baking chamber to form a magnetic field from the upper electrode to the lower electrode along the vertical direction, an upper heater over the substrate, and a controller configured to control operations of the lower heater, the lower electrode, the coil and the upper heater. The controller controls an impulse of the lamp heater.

### BRIEF DESCRIPTION OF THE DRAWINGS

Features will become apparent to those of skill in the art by describing in detail exemplary embodiments with reference to the attached drawings in which:

FIG. 1 is a cross-sectional view of a post baking apparatus in accordance with example embodiments.

FIGS. 2 and 3 are views of diffusions of an acid and a secondary electron in a photoresist film in accordance with an applying of an electromagnetic field in a post baking process.

FIG. 4 is a cross-sectional view of a post baking apparatus in accordance with example embodiments.

FIG. 5 is a cross-sectional view of a post baking apparatus in accordance with example embodiments.

FIG. 6 is a cross-sectional view of a post baking apparatus in accordance with example embodiments.

FIGS. 7 and 8 are graphs showing temperature changes of a substrate by a plate type heater and a lamp type heater in a post baking process.

FIGS. 9 and 10 are views of diffusions of an acid and a secondary electron in a photoresist film in accordance with an applying of an electromagnetic field in a post baking process.

FIG. 11 is a flow chart of an exposure method in accordance with example embodiments.

### DETAILED DESCRIPTION

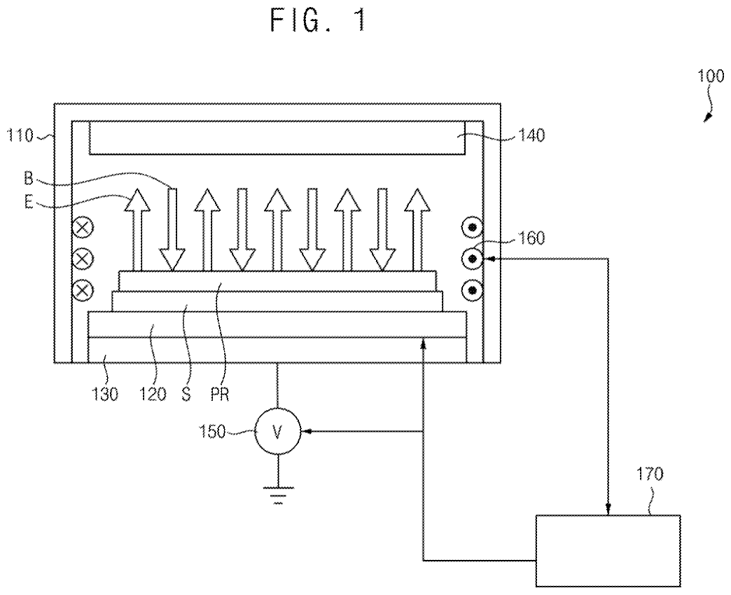

FIG. 1 is a cross-sectional view of a post baking apparatus in accordance with example embodiments. A semiconductor device may be manufactured by patterning a layer on a semiconductor substrate S. A pattern may be formed by a photolithography process, an etching process, an ion implantation process, a chemical mechanical polishing (CMP) process, a cleaning process, or a dry process. The photolithography process may include a process for forming a photoresist film on a semiconductor substrate S, a process for pre-baking the photoresist film, a process for exposing the photoresist film to form a photoresist pattern, a process for post baking the photoresist pattern, or a process for developing the photoresist pattern. The process for forming the photoresist film, the pre-baking process, the post baking process and the developing process may be performed in a spinner. As used herein, the term “or” is not an exclusive term, e.g., “A or B” would include A, B, or A and B.

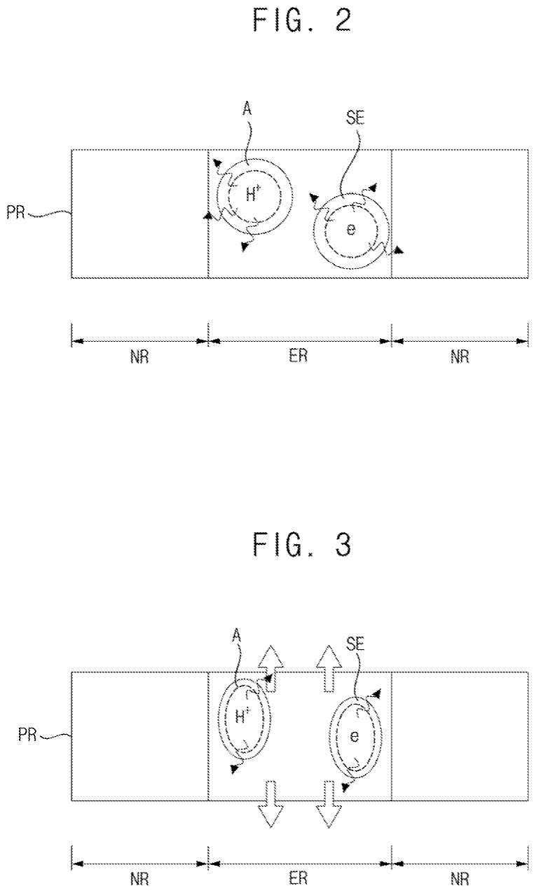

In the exposure process, a light may be irradiated to the photoresist film to expose the photoresist film. When the light includes an extreme ultraviolet (EUV) light, a number of photons, which may induce a reaction in the photoresist film, may be very small. In order to satisfy a resolution, a use proportion of a photo acid generator (PGA) as a photo-reactive material may be increased. Although the resolution may be improved by the PGA, an acid A or a secondary electron SE, which may be generated from an exposed region ER of the photoresist film PR in the exposure process, may diffuse into a non-exposed region NR of the photoresist film PR in the post baking process (See FIG. 2). The acid A or the secondary electron SE diffusing into the non-exposed region NR may deteriorate a line roughness of the photoresist film PR.

Referring to FIG. 1, a post baking apparatus 100 of example embodiments may suppress the acid A or the secondary electron SE, which may be generated from the exposed region ER of the photoresist film PR in the post baking process, from diffusing into the non-exposed region NR. The post baking apparatus 100 may include a baking chamber 110, a lower electrode 130, an applier (including the lower electrode 130, an upper electrode 140, a power source 150 and a coil 160) and a controller 170.

The baking chamber 110 may be configured to receive a substrate, e.g., a semiconductor substrate S on which the exposure process may be performed. As mentioned above, the exposed photoresist film PR may be on an upper surface of the semiconductor substrate S. Particularly, a light may be irradiated to the photoresist film PR to expose the photoresist film PR. The light may include an EUV Thus, the photoresist film PR may be divided into the exposed region ER and the non-exposed region NR.

The lower heater 120 may be in a lower region of the baking chamber 110. The semiconductor substrate S may be placed on an upper surface of the lower heater 120. The lower heater 120 may heat the semiconductor substrate S to bake the exposed photoresist film PR. In example embodiments, the lower heater 120 may include a plate heater.

In example embodiments, the lower heater 120 may function as an electrostatic chuck (ESC) configured to fix the semiconductor substrate S using an electrostatic force. In an implementation, the lower heater 120 may be in the ESC. Further, a material having a high thermal conductivity may be between the lower heater 120 and the semiconductor substrate S to increase a thermal conductivity from the lower heater 120 to the semiconductor substrate S. The material having the high thermal conductivity may include He.

The applier may be configured to form an electric field E or a magnetic field B in the baking chamber 110. In an implementation, the applier may apply the electric field E or the magnetic field B to the semiconductor substrate S on the lower heater 120. Particularly, the applier may apply the electric field E or the magnetic field B to the photoresist film PR in a vertical direction substantially perpendicular to an upper surface of the photoresist film PR. The electric field E or the magnetic field B applied to the photoresist film PR in the vertical direction may be applied to a boundary between the exposed region ER and the non-exposed region NR. Thus, the acid A or the secondary electron SE generated from the exposed region ER may be blocked by the electric field E or the magnetic field B applied to the boundary to prevent the acid A or the secondary electron SE from diffusing into the non-exposed region NR.

In example embodiments, the applier may form the electric field E and the magnetic field B in the baking chamber 110. In an implementation, the applier may apply the electric field E and the magnetic field B to the photoresist film PR in the vertical direction. The applier may include a lower electrode 130, an upper electrode 140, a power source 150 and a coil 160.

The lower electrode 130 may be on a bottom surface of the baking chamber 110. Particularly, the lower electrode 130 may be positioned under the lower heater 120. Further, an upper surface of the lower electrode 130 may contact a lower surface of the lower heater 120. In an implementation, the lower electrode 130 may be spaced apart from the lower heater 120. The power source 150 may be connected to the lower electrode 130 to supply power to the lower electrode 130.

The upper electrode 140 may be in an upper region of the baking chamber 110. In an implementation, the upper electrode 140 may be on a lower surface of a ceiling of the baking chamber 110. The upper electrode 140 and the lower electrode 130 may form the electric field E in the baking chamber 110 along the vertical direction. Particularly, the electric field E may be formed from the lower electrode 130 to the upper electrode 140. Thus, the electric field E may be applied into the photoresist film PR, particularly, the boundary between the exposed region ER and the non-exposed region NR through a lower surface of the photoresist film PR.

The coil 160 may be on an inner sidewall of the baking chamber 110. Particularly, the coil 160 may be configured to surround the semiconductor substrate S. The coil 160 may form the magnetic field B in the baking chamber 110 along the vertical direction. Particularly, the magnetic field B may be formed from the upper electrode 140 to the lower electrode 130. In an implementation, a direction of the magnetic field B may be opposite to a direction of the electric field E. Thus, the magnetic field B may be applied into the photoresist film PR, particularly, the boundary between the exposed region ER and the non-exposed region NR through an upper surface of the photoresist film PR. Further, the electric field E and the magnetic field B in the baking chamber 110, e.g., an electromagnetic field may be measured from a current induced to the coil 160.

The controller 170 may be configured to control an operation of the lower heater 120. In an implementation, the controller 170 may control a temperature of the semiconductor substrate S, particularly, a temperature of the exposed photoresist film PR by the lower heater 120.

The controller 170 may control an operation of the power source 150. In an implementation, the controller 170 may control the vertical electric field E between the upper electrode 140 and the lower electrode 130. Further, the controller 170 may control an operation of the coil 160. In an implementation, the controller 170 may control the vertical magnetic field B in the baking chamber 110. As mentioned above, the controller 170 may measure the electromagnetic field in the baking chamber 110 from the current induced to the coil 160.

According to example embodiments, the electric field E and the magnetic field B formed by the applier may be applied to the boundary between the exposed region ER and the non-exposed region NR of the photoresist film PR to suppress the horizontal diffusion of the acid A or the secondary electron SE in the exposed region ER into the non-exposed region NR. Further, when the acid A is concentrated on a specific region of the photoresist film PR by the diffusion of the acid A, the concentrated acid A may act as a defect of the photoresist film PR. In this case, the controller 170 may alternately control the electric field E and the magnetic field B to remove the defect. In other words, the controller 170 may activate the electric field E while deactivating the magnetic field B, and then activate the magnetic field B while deactivating the electric field E. The controller may repeat this process until the defect is removed, specifically, that the concentration of the acid A on a specific region of the photoresist film PR has been diffused.

FIGS. 2 and 3 are views of diffusions of an acid and a secondary electron in a photoresist film in accordance with an applying of an electromagnetic field in a post baking process. FIG. 2 may show the diffusions of the acid A and the secondary electron SE in the photoresist film PR when the electric field E and the magnetic field B may not be applied to the photoresist film PR in the post baking process. As shown in FIG. 2, the acid A and the secondary electron SE generated in the exposed region ER may diffuse into the non-exposed region NR along the horizontal direction.

In contrast, FIG. 3 may show the diffusions of the acid A and the secondary electron SE in the photoresist film PR when the electric field E and the magnetic field B may be applied to the photoresist film PR in the post baking process. As shown in FIG. 3, the acid A and the secondary electron SE generated in the exposed region ER may not diffuse into the non-exposed region NR along the horizontal direction by the electric field E and the magnetic field B.

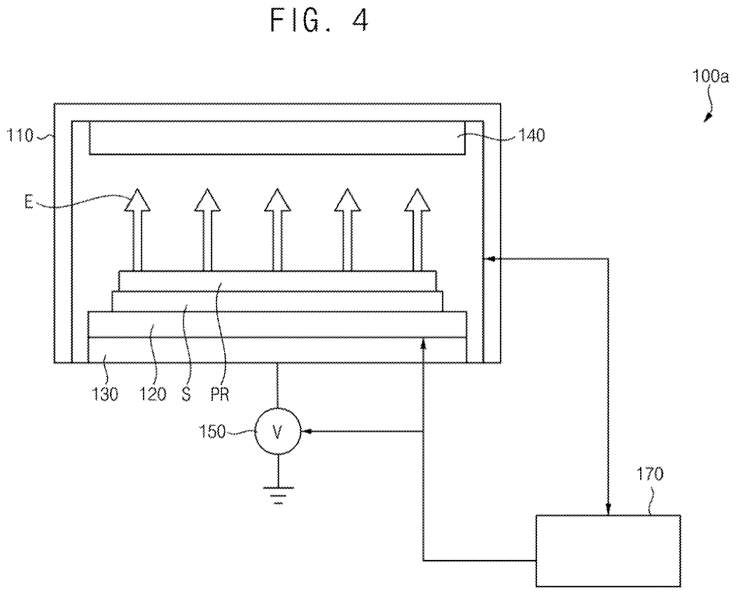

FIG. 4 is a cross-sectional view of a post baking apparatus in accordance with example embodiments. A post baking apparatus 100a of example embodiments may include elements substantially the same as those of the post baking apparatus 100 in FIG. 1 except for an applier. Thus, the same reference numerals may refer to the same elements and any further illustrations with respect to the same elements may be omitted herein for brevity.

Referring to FIG. 4, an applier of example embodiments may include only the lower electrode 130 and the upper electrode 140. In an implementation, the applier may not include the coil 160. Thus, the applier may apply only the electric field E to the exposed photoresist pattern PR along the vertical direction. Because the magnetic field B formed by the coil 160 may not be applied to the exposed photoresist film PR, only the electric field E may suppress the horizontal diffusion of the acid A or the secondary electrode SE.

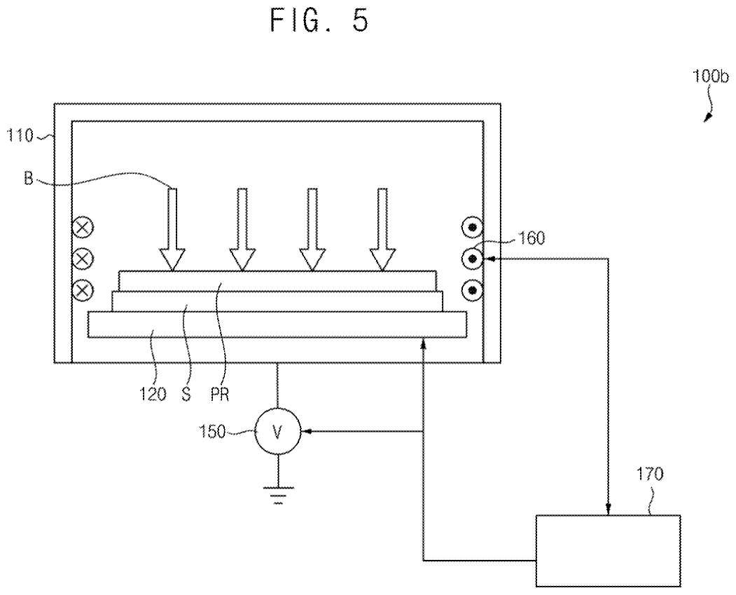

FIG. 5 is a cross-sectional view of a post baking apparatus in accordance with example embodiments. A post baking apparatus 100b of example embodiments may include elements substantially the same as those of the post baking apparatus 100 in FIG. 1 except for an applier. Thus, the same reference numerals may refer to the same elements and any further illustrations with respect to the same elements may be omitted herein for brevity.

Referring to FIG. 5, an applier of example embodiments may include only the coil 160. In an implementation, the applier may not include the upper electrode 140 and the lower electrode 130. Thus, the applier may apply only the magnetic field B to the exposed photoresist pattern PR along the vertical direction. Because the electric field E by the upper electrode 140 and the lower electrode 130 may not be applied to the exposed photoresist film PR, only the magnetic field B may suppress the horizontal diffusion of the acid A or the secondary electrode SE.

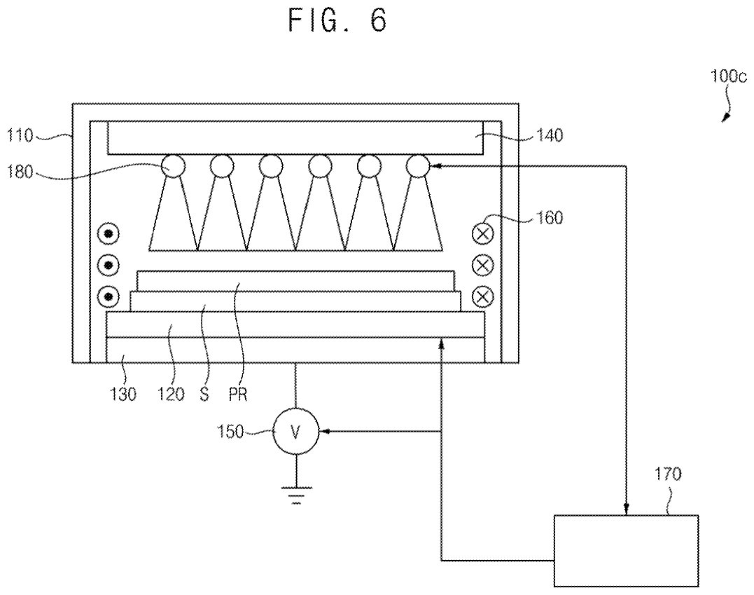

FIG. 6 is a cross-sectional view of a post baking apparatus in accordance with example embodiments. A post baking apparatus 100c of example embodiments may include elements substantially the same as those of the post baking apparatus 100 in FIG. 1 except for further including an upper heater. Thus, the same reference numerals may refer to the same elements and any further illustrations with respect to the same elements may be omitted herein for brevity.

Referring to FIG. 6, the post baking apparatus 100c of example embodiments may further include an upper heater 180. The upper heater 180 may be in the upper region of the baking chamber 110. The upper heater 180 may rapidly heat the exposed photoresist film PR to induce reactions of the acid A and the secondary electron SE in the photoresist film PR.

In example embodiments, the upper heater 180 may include a lamp heater. The controller 170 may control an operation of the upper heater 180. Particularly, the controller 170 may control an impulse of the upper heater 180 as the lamp heater to control the heat, e.g., an amount of energy applied to the exposed photoresist film PR. Thus, the lamp heater may rapidly apply high energy to the photoresist film PR to suppress the horizontal diffusion of the acid A or the secondary electrode SE in the exposed region ER into the non-exposed region NR. Alternatively, the post baking apparatus 100c of example embodiments may include the structure in FIG. 4 or the structure in FIG. 5.

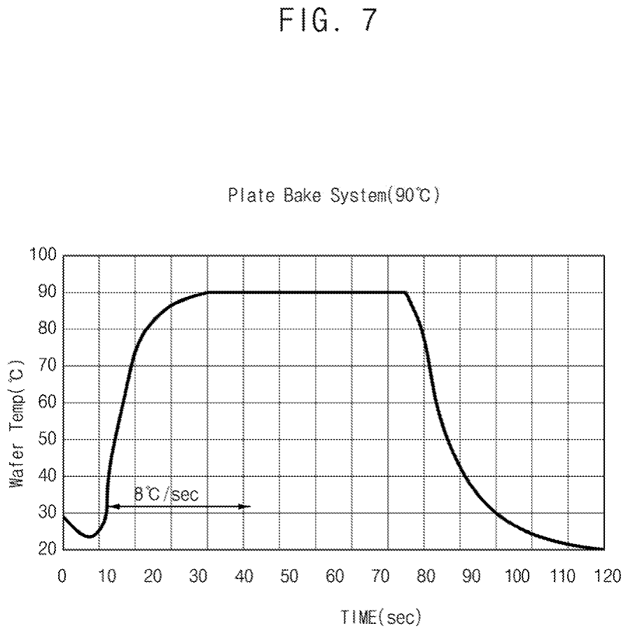

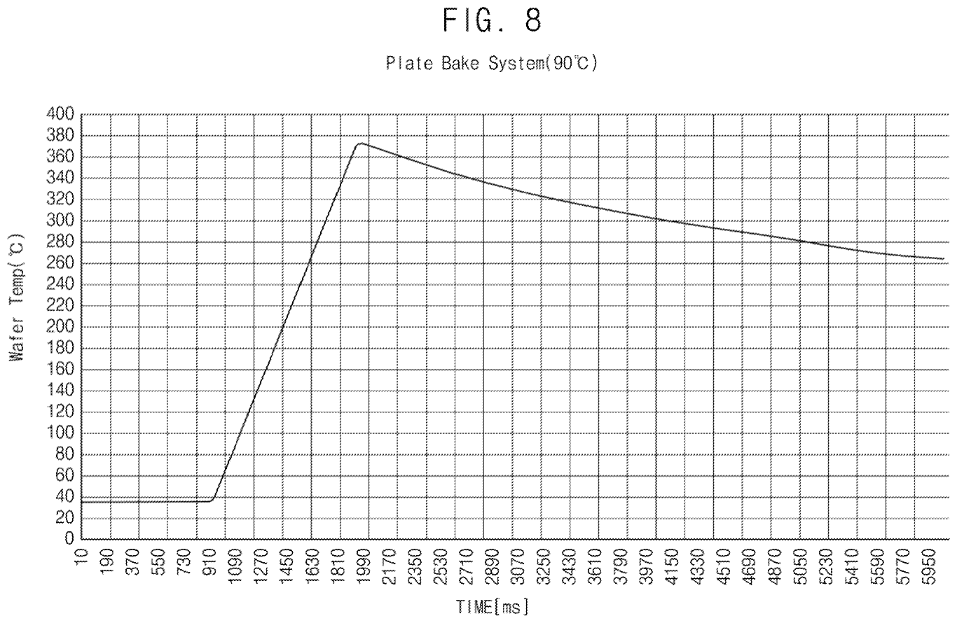

FIGS. 7 and 8 are graphs showing temperature changes of a substrate by a plate type heater and a lamp type heater in a post baking process. As shown in FIG. 7, when the semiconductor substrate S may be heated by the plate heater, a temperature change may be about 8° C./sec. In contrast, as shown in FIG. 8, when the semiconductor substrate S may be heated by the lamp heater, a temperature change may be about 300° C./sec. Thus, it can be noted that the lamp heater may rapidly apply the high energy to the photoresist film PR.

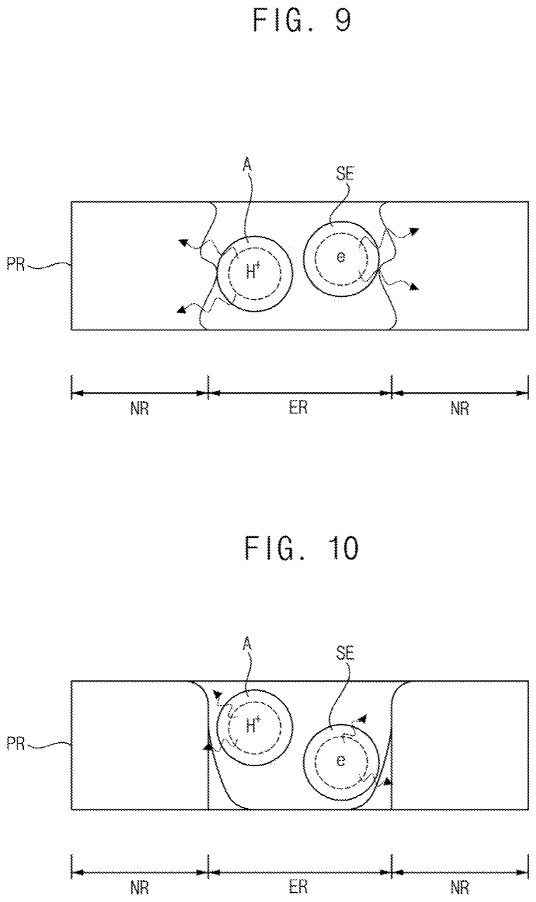

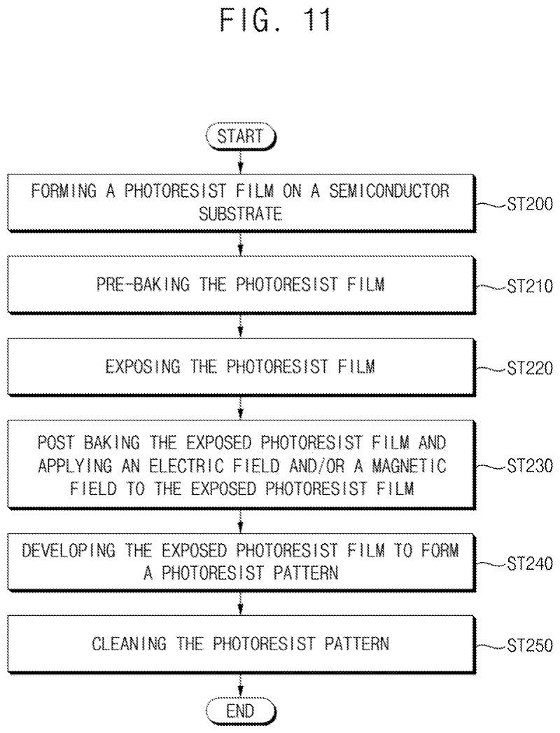

FIGS. 9 and 10 are views of diffusions of an acid and a secondary electron in a photoresist film in accordance with an applying of an electromagnetic field in a post baking process. FIG. 9 may show the diffusions of the acid A and the secondary electron SE in the photoresist film PR when the electric field E and the magnetic field B may not be applied to the photoresist film PR in the post baking process. As shown in FIG. 9, the acid A and the secondary electron SE generated in the exposed region ER may diffuse into the non-exposed region NR along the horizontal direction.

In contrast, FIG. 10 may show the diffusions of the acid A and the secondary electron SE in the photoresist film PR when the electric field E and the magnetic field B may be applied to the photoresist film PR and the semiconductor substrate S may be heated by the upper heater 180 and the lower heater 120 in the post baking process. As shown in FIG. 10, the acid A and the secondary electron SE generated in the exposed region ER may not diffuse into the non-exposed region NR along the horizontal direction by the electric field E and the magnetic field B.

FIG. 11 is a flow chart of an exposure method in accordance with example embodiments. Referring to FIG. 11, in step ST200, the photoresist film PR may be on the semiconductor substrate S.

In step S210, the photoresist film PR may be pre-baked. The pre-baking may be performed using the post baking apparatus of example embodiments. In step ST220, the photoresist film PR may be exposed. In an implementation, an EUV may be irradiated to the photoresist film PR through a mask pattern to form the exposed region ER and the non-exposed region NR in the photoresist film PR. In step ST230, the exposed photoresist film PR may be post baked. Particularly, the electric field E or the magnetic field B may be vertically applied to the exposed photoresist film PR to control the horizontal diffusions of the acid A or the secondary electron SE generated from the exposed photoresist film PR.

Particularly, the electric field E or the magnetic field B may be applied to the boundary between the exposed region ER and the non-exposed region NR of the photoresist film PR to suppress the horizontal diffusions of the acid A or the secondary electron SE in the exposed region ER into the non-exposed region NR. Further, the applying of the electric field E and the magnetic field B may be alternately controlled to remove the acid A concentrated on a specific region of the photoresist film PR by the diffusion of the acid A.

In example embodiments, the electric field E may be upwardly applied to the lower surface of the photoresist film PR in the vertical direction. The magnetic field B may be downwardly applied to the upper surface of the photoresist film PR in the vertical direction.

In step ST240, the photoresist film PR may be developed to form a photoresist pattern. In step ST250, the photoresist pattern may then be cleaned to remove particles from the photoresist pattern.

According to example embodiments, the electric field may be applied to the photoresist film in the vertical direction using the upper electrode and the lower electrode. The magnetic field may be applied to the photoresist film in the vertical direction using the coil. Thus, the horizontal diffusion of the acid or the secondary electron generated from the exposed photoresist film may be controlled by the electric field or the magnetic field. Particularly, the electromagnetic field in the vertical direction may prevent the acid or the secondary electron from diffusing in the horizontal direction to suppress the acid or the secondary electron from infiltrating into a non-exposed region of the exposed photoresist film. Thus, a distortion of the photoresist pattern, particularly, a deterioration of a line roughness in the photoresist pattern, which may be caused by the acid or the secondary electron, may be suppressed. As a result, a pattern error may also be prevented so that a desired pattern may be accurately formed.

By way of summation and review, example embodiments relate to an apparatus for baking an exposed photoresist film and a method of exposing a photoresist film using the baking apparatus. The photolithography process may include a process for forming a photoresist film on a semiconductor substrate, a process for pre-baking the photoresist film, a process for exposing the photoresist film to form a photoresist pattern, a process for post baking the photoresist pattern, or a process for developing the photoresist pattern. In order to form a fine photoresist pattern, the exposure process may use an extreme ultraviolet (EUV) light.

According to related arts, the post baking process may be performed using a post baking apparatus including a heater. The heater may be under the semiconductor substrate to bake the photoresist pattern.

During the post baking process, an acid or a secondary electron generated from an exposed portion of the photoresist film may horizontally diffuse. The diffusing aid or the secondary electron may infiltrate into a non-exposed portion of the photoresist film. The acid or the secondary electron diffusing into the non-exposed portion of the photoresist film may distort the photoresist pattern. Particularly, the acid or the secondary electron may deteriorate line roughness of the photoresist pattern. A pattern formed from a layer using the distorted photoresist pattern may also have a distorted shape. As a result, a pattern error may be generated.

Example embodiments provide a post baking apparatus that may be capable of controlling a diffusion of an acid or a secondary electron in a photoresist. Example embodiments also provide an exposure method using the above-mentioned post baking apparatus.

According to example embodiments, the electric field may be applied to the photoresist film in the vertical direction using the upper electrode and the lower electrode. The magnetic field may be applied to the photoresist film in the vertical direction using the coil. Thus, the horizontal diffusion of the acid or the secondary electron generated from the exposed photoresist film may be controlled by the electric field or the magnetic field. Particularly, the electromagnetic field in the vertical direction may prevent the acid or the secondary electron from diffusing in the horizontal direction to suppress the acid or the secondary electron from infiltrating into a non-exposed region of the exposed photoresist film. Thus, a distortion of the photoresist pattern, particularly, a deterioration of a line roughness in the photoresist pattern, which may be caused by the acid or the secondary electron, may be suppressed. As a result, a pattern error may also be prevented so that a desired pattern may be accurately formed.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, or elements described in connection with a particular embodiment may be used singly or in combination with features, characteristics, or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A post baking apparatus comprising:
a baking chamber configured to receive a substrate with an exposed photoresist film;
a lower heater in the baking chamber under the substrate to heat the exposed photoresist film;
an applier applying an electric field or a magnetic field to the exposed photoresist film along a vertical direction, which is substantially perpendicular to an upper surface of the exposed photoresist film, to control diffusions of an acid or a secondary electron, which are generated from the exposed photoresist film, along a horizontal direction; and
a controller configured to control an operation of the applier.

2. The post baking apparatus as claimed in claim 1, wherein the applier includes:
a lower electrode under the lower heater; and
an upper electrode over the substrate to form the electric field between the lower electrode and the upper electrode along the vertical direction.

3. The post baking apparatus as claimed in claim 2, wherein the electric field is formed from the lower electrode to the upper electrode along the vertical direction.

4. The post baking apparatus as claimed in claim 2, wherein the applier further includes a power source connected to the lower electrode.

5. The post baking apparatus as claimed in claim 2, wherein the applier further includes a coil on an inner sidewall of the baking chamber to form the magnetic field along the vertical direction.

6. The post baking apparatus as claimed in claim 5, wherein the magnetic field is formed from the upper electrode to the lower electrode along the vertical direction.

7. The post baking apparatus as claimed in claim 5, wherein the controller controls operations of the lower electrode and the coil.

8. The post baking apparatus as claimed in claim 1, wherein the controller controls an operation of the lower heater.

9. The post baking apparatus as claimed in claim 1, wherein the lower heater includes a plate heater.

10. The post baking apparatus as claimed in claim 1, further comprising an upper heater over the substrate.

11. The post baking apparatus as claimed in claim 10, wherein the upper heater includes a lamp heater.

12. The post baking apparatus as claimed in claim 11, wherein the controller controls an impulse of the lamp heater.

13. A post baking apparatus comprising:
a baking chamber configured to receive a substrate with an exposed photoresist film;
a lower heater in the baking chamber under the substrate to heat the exposed photoresist film;
a lower electrode under the lower heater;
an upper electrode over the substrate to form an electric field from the lower electrode to the upper electrode along a vertical direction;
a coil on an inner sidewall of the baking chamber to form a magnetic field from the upper electrode to the lower electrode along the vertical direction; and
a controller configured to control operations of the lower heater, the lower electrode and the coil.

14. The post baking apparatus as claimed in claim 13, wherein the lower heater includes a plate heater.

15. The post baking apparatus as claimed in claim 13, further comprising an upper heater over the substrate.

16. The post baking apparatus as claimed in claim 15, wherein the controller controls an operation of the upper heater.

17. The post baking apparatus as claimed in claim 15, wherein the upper heater includes a lamp heater.

18. A post baking apparatus comprising:
a baking chamber configured to receive a substrate with an exposed photoresist film;
a lower heater in the baking chamber under the substrate to heat the exposed photoresist film;
a lower electrode under the lower heater;
an upper electrode over the substrate to form an electric field from the lower electrode to the upper electrode along a vertical direction;
a coil on an inner sidewall of the baking chamber to form a magnetic field from the upper electrode to the lower electrode along the vertical direction;
an upper heater over the substrate; and.
a controller configured to control operations of the lower heater, the lower electrode, the coil and the upper heater,
wherein the controller controls an impulse of the lamp heater.

19. The post baking apparatus as claimed in claim 18, wherein the lower heater includes a plate heater.

20. The post baking apparatus as claimed in claim 18, wherein the upper heater includes a lamp heater.
